(19) United States
(12) Patent Application Publication
(10) Pub. No.: US 2011/0117696 A1
(43) Pub. Date: May 19, 2011

(54) CdTe SURFACE TREATMENT FOR STABLE BACK CONTACTS

(75) Inventor: Matthew L. FISHER, Allen, TX (US)

(73) Assignee: Air Liquide Electronics U.S. LP, Dallas, TX (US)

(21) Appl. No.: 12/949,537

(22) Filed: Nov. 18, 2010

Related U.S. Application Data
(60) Provisional application No. 61/262,817, filed on Nov. 19, 2009.

(51) Int. Cl. H01L 21/306; C09K 13/00

(52) U.S. Cl. 438/102; 252/79.1; 257/E21.219

(57) ABSTRACT

Disclosed are etching compositions and processes of using the same for etching the surface of CdTe-containing layers.

### CROSS-REFERENCE TO RELATED APPLICATIONS

This application claims the benefit under 35 U.S.C. §119(e) to provisional application No. 61/262,817, filed Nov. 19, 2009, the entire contents of which are incorporated herein by reference.

### BACKGROUND

Common etchants for CdTe-containing layers include NP (an aqueous nitric acid-phosphoric acid mixture), dilute bromine (in a solvent such as methanol), and dichromate solutions (acidic solution of K₂Cr₂O₇), or a combination such as BDH (bromine methanol etch followed by dichromate solution, followed by hydrazine treatment). See, e.g., McCandless et al., Processing Options for CdTe Thin Film Solar Cells, Solar Energy Vol 77, Issue 6, December 2004 p. 848; U.S. Pat. No. 4,456,630, col. 1, lines 23-29.

NP is an aggressive etch that can form a thick layer of elemental tellurium in a short amount of time. McCandless at 850. However NP may result in grain boundary attack. See, e.g., Background of U.S. Pat. No. 4,319,069 to Tyan. NP may also leave the Te-rich surface in a condition susceptible to oxidation. McCandless at 850. Large volumes of concentrated phosphoric acid with strong acids such as nitric may also be difficult to handle in a high volume manufacturing facility where the wastewater pH must be strictly controlled on the alkaline side of neutral in order to capture any dissolved cadmium species.

Similar arguments may be made against solutions of dichromate combined with strong acids, such as sulfuric acid, at least because Cr+6 compounds are highly toxic and carcinogenic.

Bromine solutions are unstable (give off toxic vapors). While they may be freshly prepared and used effectively in a laboratory setting, implementation in a high volume manufacturing environment would be difficult.

McCandless at pp. 839-56 summarizes a variety of processing options for CdTe Thin Film Solar Cells. Included is a discussion of the variety of chemicals used for etching CdTe-containing layers prior to back contact formation, including nitric-phosphoric, bromine-methanol, BDH, hydrazine, hydrogen peroxide, thiosulfate, acidified dichlormate, citric acid, ammonia, alkali metal hydroxides, and diaminoethane. Id. at 848. Also discussed are the uses of various copper sources (effects of using different complexing agents with Cu as the means for delivering the copper onto the CdTe-containing layer after etching). Id. at 851.

U.S. Pat. No. 4,456,630 to Basol discloses a process for treating CdTe-containing layers wherein the layers are etched with an acidic solution (preferably an oxidizing acid solution), followed by treatment with a basic solution, followed by deposition of a conductive metal. The oxidizing agents are preferably dichromate or peroxide, the acids are preferably sulfuric, nitric, hydrochloric or hydrofluoric acid, and the basic compounds are preferably hydrazine or an alkali metal hydroxide solution.

A need remains for etching compositions and methods for etching the surface of a CdTe-containing layers in the manufacturing process for thin film solar cells.

### SUMMARY

Disclosed are methods for etching the surface of a CdTe-containing layer. A CdTe-containing layer is provided and an etching composition is provided to etch at least part of the CdTe-containing layer. The etching composition comprises an acid, an oxidizer, and a complexing agent. The disclosed methods may further include one or more of the following aspects:
providing the etching composition comprising spraying the etching composition on the CdTe-containing layer;
providing the etching composition comprising moving the CdTe-containing layer through a tank containing the etching composition;
providing the etching composition for a time period ranging from approximately 1 second to approximately 60 seconds;
the etching composition not being rinsed by deionized water from the CdTe-containing layer;
the etching composition being provided at room temperature;
the etching composition having a pH ranging from approximately 1 to approximately 5;
the oxidizer being hydrogen peroxide;
the acid being selected from the group consisting of gluconic acid, acetic acid, citric acid, and mixtures thereof; and
the complexing agent being selected from the group consisting of benzotriazole, cysteine, a glycolic acid ethoxylate lauryl ether surfactant, a polyethylene glycol surfactant, and mixtures thereof.

Also discloses are methods for etching the surface of a CdTe-containing layer. A CdTe-containing layer is provided and an etching composition is provided to etch at least part of the CdTe-containing layer. The etching composition comprises a first mixture containing an acid and an oxidizer and a second mixture containing a complexing agent. The disclosed methods may further include one or more of the following aspects:
providing the etching composition comprising spraying the first mixture on the CdTe-containing layer followed by spraying the second mixture on the CdTe-containing layer;
providing the etching composition comprising moving the CdTe-containing layer through a first tank containing the first mixture and a second tank containing the second mixture;
further comprising rinsing the CdTe-containing layer after moving the CdTe-containing layer through the first tank containing the first mixture and prior to moving the CdTe-containing layer through the second tank containing the second mixture;
the first mixture being provided for a time period ranging from approximately 1 second to approximately 60 seconds;
the etching composition being provided at room temperature;
the oxidizer being hydrogen peroxide;
the acid being selected from the group consisting of gluconic acid, acetic acid, citric acid, and mixtures thereof; and
the complexing agent being selected from the group consisting of benzotriazole, cysteine, a glycolic acid ethoxylate lauryl ether surfactant, a polyethylene glycol surfactant, and mixtures thereof.

Also disclosed are compositions for etching a CdTe-containing layer. The compositions comprise between approximately 5% w/w to approximately 50% w/w of an acid; between approximately 0.5% w/w to approximately 5% w/w of an oxidizer; and between approximately 0.01% w/w to approximately 3% w/w of a complexing agent. The disclosed compositions may further include one or more of the following aspects:
the oxidizer being hydrogen peroxide;
the acid being selected from the group consisting of gluconic acid, acetic acid, citric acid, and mixtures thereof; and
the complexing agent being selected from the group consisting of benzotriazole, cysteine, a glycolic acid ethoxylate lauryl ether surfactant, a polyethylene glycol surfactant, and mixtures thereof.

### DETAILED DESCRIPTION

Described are etching compositions and processes of using the same for etching the surface of CdTe-containing layers. The disclosed etching compositions and processes may be useful in the manufacture of semiconductor, photovoltaic, LCD-TFT, or flat panel type devices, more preferably in the formation of thin film solar cells before applying the back contact.

The disclosed etching compositions contain an acid, an oxidizer, and a complexing agent. In a first embodiment, the disclosed etching compositions are one mixture comprising the acid, the oxidizer, and the complexing agent, and preferably consisting of the acid, the oxidizer, the complexing agent, and water. In a second embodiment, the disclosed etching compositions are two mixtures, with the first mixture containing the acid and oxidizer and the second mixture containing the complexing agent. Use of the second embodiment may be required, for example, when the preferred complexing agent is not capable of being dissolved in the acid/oxidizer mixture or when the complexing agent is not compatible with the oxidizer. The first embodiment and the first mixture of the second embodiment of the disclosed etching compositions have a pH ranging from approximately 1 to approximately 5, and preferably from approximately 2 to approximately 4. The second mixture has a relatively neutral pH, which may range from approximately 2 to approximately 12, and preferably from approximately 4 to approximately 10.

The complexing agent is preferably a copper complexing agent. Applicants believe that the complexing agent remains on the surface of the CdTe-containing layer after etching, where it reacts with the Cu dopant to prevent Cu migration into the CdTe-containing layer. The concentration of the complexing agent in the etching composition ranges from approximately 0.01% w/w to approximately 3% w/w, and preferably from approximately 0.5% w/w to approximately 1.25% w/w. In the first embodiment, the complexing agent may be mixed with the etching composition itself. In the second embodiment, the complexing agent may be provided in a second mixture containing a suitable solvent. Complexing agents that may not be soluble and/or compatible with the acid/oxidizing agent mixture may be dissolved in a polar solvent, such as water or a basic water solution. In either embodiment, the goal is for the complexing agent to form a uniform layer on the CdTe surface rather than aggregating.

Complexing agents capable of forming complexes with Cu include azoles (triazoles, thiazoles, tetrazoles, imidazoles and the like including but not limited to benzotriazole, triazole, imidazole, mercaptobenzotriazole aminotetrazole, aminothiazole, aminomercaptothiadiazole, dimercaptothiadiazole, mercaptothiazdoline, etc.), mercapto compounds (cysteine, mercaptopropionic acid, mercaptoacetic acid, thioglycerol, mercaptoethanol, mercaptobenzoic acid, dimercaptosuccinic acid, sulfosalicylic acid, etc.), amino acids (glycine, histidine, cysteine, aspartic acid, proline, etc.), organic amines (monoisopropanolamine, diemthylethanolamine, aminoethylaminoethanol, ethylenediamine, etc.), surfactants containing functional groups capable of complexing copper (such as carboxylate, phosphate, sulfate, sulfonate, etc.), and mixtures thereof. The complexing agent may also include polyethylene glycol surfactants, such as PEG 3400, which for reasons unbeknownst to Applicants, do not complex with copper in the classical sense of complexing but appear to retard copper diffusion into the CdTe-containing layer. Preferably, the complexing agent is an azole, mercapto compound, or surfactant. More preferably, the complexing agent is benzotriazole, cysteine, a glycolic acid ethoxylate lauryl ether surfactant, or a polyethylene glycol surfactant.

In a least preferred alternative of the second embodiment, the second mixture may further contain the dopant used to form the back contact. For example, the second mixture may comprise a mixture of the polyethylene glycol complexing agent and copper powder. The second mixture should not contain a mixture of the dopant and a strong complexing agent, such as cysteine or benzotriazole, because the dopant and the complexing agent may react in the mixture. If the dopant and complexing agent react in the mixture, the dopant may be not be able to be incorporated into the surface of the CdTe-containing layer. Consequently, the reaction of dopant and complexing agent in the second mixture may prevent the dopant from serving its intended purpose. As a result, this alternative is least preferred.

The concentration of the acid in the etching compositions ranges from approximately 5% w/w to approximately 50% w/w, and preferably from approximately 15% w/w to approximately 35% w/w. Preferably, the acid is not a strong inorganic acid, but rather an organic acid or a weaker inorganic acid in order to prevent the etching compositions from attacking the grain boundaries and leaving pathways for copper to diffuse into the bulk of the CdTe-containing layer. Preferable acids include organic acids such as acetic, propionic, formic, citric, tartaric, gluconic, lactic, malic, succinic, maleic, malonic, oxalic, etc., or weaker inorganic acids such as phosphonic acids (excluding nitric and phosphoric acids).

The concentration of the oxidizer in the etching compositions ranges from approximately 0.5% w/w to approximately 5% w/w, and preferably from approximately 0.75% w/w to approximately 1.5% w/w Preferable oxidizing agents include hydrogen peroxide, ammonium persulfate, ammonium perchlorate, ammonium periodate (both IO4- and IO6 5- , but preferably IO4-), etc., but exclude dichromate. Even more preferably, the oxidizing agent is hydrogen peroxide.

The etching compositions contain between approximately 50% w/w and approximately 95% w/w water, preferably between about 65% w/w and about 85% w/w, and, as discussed above, no strong acids, in order to be more easily handled by wastewater and neutralization facilities. The disclosed etching compositions are less aggressive than prior art solutions towards the CdTe-containing layer, and result in less attack on the grain boundaries as compared to nitric acid/phosphoric acid mixture (NP) etching, leaving less of a pathway for Cu diffusion. In addition, the complexing agent residue may keep the Cu in the vicinity of the back contact rather than allowing it to move towards the CdS junction.

Some exemplary etching compositions include:

(1) 25% w/w Acetic Acid, 0.75% w/w Hydrogen Peroxide, 1% w/w Polyethylene glycol surfactant, with the balance water;

(2) 20% w/w Citric Acid, 0.75% w/w Hydrogen Peroxide, 0.5% w/w Cysteine, with the balance water;

(3) 25% w/w Gluconic Acid, 0.75% w/w Hydrogen Peroxide, 0.5% w/w Benzotriazole, with the balance water;

(4) First Mixture=15% w/w Citric Acid and 0.75% w/w Hydrogen Peroxide, with the balance water; Second Mixture=0.5% w/w Cysteine in water; and

(5) First Mixture=25% w/w Gluconic Acid and 1% w/w Hydrogen Peroxide, with the balance water; Second Mixture=0.5% w/w Benzotriazole in water.

The disclosed etching compositions may be used in a method to etch at least part of a CdTe-containing layer. In the second embodiment, the first mixture etches at least part of the CdTe-containing layer while the second mixture deposits the complexing agent on at least part of the CdTe-containing layer. In most embodiments, the CdTe-containing layer consists of Cd and Te. However, the disclosed etching compositions may also be used to etch a CdTe-containing layer containing other elements, such as Hg, Zn, Co, Ag, and/or Au.

The CdTe-containing layer is grown in a superstrate configuration (i.e. upside-down) on a glass substrate having one or more layers previously deposited thereon. The glass substrate is located above the layers included in the solar cell. The one or more layers may include a transparent conducting oxide layer, which may be zinc oxide doped with aluminum; an indium tin oxide layer; and a CdS layer. The CdTe-containing layer is most commonly grown adjacent to the CdS layer.

The CdTe-containing layer may be sprayed with a solution of CdCl₂ and subject to heat treatment at approximately 400° C. The CdCl₂ spray increases the CdTe grain growth and somehow improves defects in the CdTe-containing layer.

In the first embodiment, the disclosed etching compositions may be provided to etch at least part of the CdTe-containing layer. Similarly, in the second embodiment, the first mixtures may be provided to etch at least part of the CdTe-containing layer. The etching compositions/first mixtures may be sprayed on the surface of the CdTe-containing layer. Alternatively, the CdTe-containing layer may be placed in or moved through a tank containing the etching compositions/first mixtures, for example, on a conveyor belt assembly.

As demonstrated in the examples that follow, the disclosed etching compositions/first mixtures modify the surface of the CdTe-containing layer to a tellurium-rich and oxide-free layer. The CdTe-containing layer changes from a grayish color to a silver color during the etching step due to the removal of Cd from the outer portions of the CdTe-containing layer.

The first embodiment of the disclosed etching compositions preferably leave behind a uniform layer of organic residue capable of complexing metals, such as copper, that are subsequently added to create the back contact. In the second embodiment, the organic residue is provided by the second mixtures.

The disclosed etching compositions may be provided to etch the CdTe-containing layer for a time period ranging from approximately 1 second to approximately one minute, preferably from approximately 5 seconds to approximately 30 seconds. For example, the CdTe-containing layer may be sprayed with the disclosed etchings compositions for 15 seconds. Alternatively, the duration of time the CdTe-containing layer passes through the tank of etching composition may be 5 seconds. One of ordinary skill in the art will recognize that thicker CdTe-containing layers may require a longer time period and thinner layers may require a shorter time period.

The disclosed etching compositions are less aggressive than prior art etching compositions and therefore may be applied to thinner CdTe-containing layers for longer periods of time. By being less aggressive, the disclosed etching compositions allow for wider manufacturing process windows than the prior art etching compositions, which provides more flexibility in the manufacturing process and the potential ability to recover from human and/or mechanical error. For example, if the prior art etching composition contacts the CdTe-containing layer for too long a period of time, due to either human or mechanical error, the CdTe-containing layer may become defective, rendering the entire solar cell defective. Current solar cell manufacturing processes typically contact the CdTe-containing layer with the etching compositions in the range of seconds. Applicants believe that the CdTe-containing layer may not be rendered defective if the disclosed etching compositions accidentally remain in contact with the layer for seconds beyond the planned contact time.

The disclosed method may occur at room temperature, although it is not limited to this temperature. Room temperature may range from approximately 19° C. to approximately 30° C. One of ordinary skill in the art will recognize that the etching process will occur more quickly at higher temperatures and more slowly at cooler temperatures. One of ordinary skill in the art will further recognize that providing the etching compositions at too high a temperature (for example, at or near the boiling point of the etching composition) will result in complete dissolution of the CdTe-containing layer, as well as layers adjacent to the CdTe-containing layer.

The etching compositions may not need to be rinsed from the CdTe-containing layer by deionized water after the etching step. The disclosed etching compositions are less aggressive than the prior art etching compositions, resulting in a much slower etch rate. The next processing step may provide sufficient dilution to prevent the etching compositions from substantially attacking the CdTe-containing layer. Removing the rinsing step from the prior art etching process also provides for improved manufacturing efficiencies by reducing the total number of steps in the manufacturing process.

Alternatively, the CdTe-containing layer may be subject to a minimal rinse with deionized water to dilute the etching composition or exposed to a flow of air (blown dry) to remove excess etching composition. In another alternative, particularly applicable to the second embodiment, the first mixture of the etching composition may be rinsed from the CdTe-containing layer by methods known to those of ordinary skill in the art or the second mixture may serve as the rinse for the first mixture.

In the second embodiment, the second mixture may be provided to deposit the complexing agent and/or the doping agent on a surface of the CdTe-containing layer. Preferably, the second mixture deposits the complexing agent in a uniform layer. The second mixture may be sprayed on the surface of the CdTe-containing layer. Alternatively, the CdTe-containing layer may move through a tank containing the second mixture, for example, on a conveyor belt assembly. In one exemplary method, the CdTe-containing layer may move on a conveyor belt assembly through a tank containing the first mixture, a rinse tank, and a tank containing the second mixture.

The second mixture may be provided to deposit the complexing agent and/or doping agent on a surface of the CdTe-containing layer for a time period ranging from approximately 30 seconds to approximately 1 minute. For example, the CdTe-containing layer may be sprayed with the second mixture for 45 seconds. Alternatively, the duration of time the CdTe-containing layer passes through the tank containing the second mixture may be 35 seconds. One of ordinary skill in the art will recognize that the amount of time required may vary due to factory throughput considerations.

As in the first embodiment, provision of the second mixture to the CdTe-containing layer may occur at room temperature, although it is not limited to this temperature. Room temperature may range from approximately 19° C. to approximately 30° C. One of ordinary skill in the art will recognize that the deposition process will occur more quickly at higher temperatures and more slowly at cooler temperatures. One of ordinary skill in the art will further recognize that providing the second mixture at too high a temperature (for example, at or near the boiling point of the second mixture) may result in complete dissolution of the CdTe-containing layer, as well as layers adjacent to the CdTe-containing layer.

As stated with respect to the discussion of the etching composition and in either embodiment, it is preferable that the complexing agent remains in a uniform layer on the surface of the CdTe-containing layer after etching, where it reacts with the Cu doping agent to prevent Cu migration into the CdTe-containing layer.

When not already contained in the second mixture, a doping agent, such as copper or copper/carbon mixture, may be sprayed onto the etched CdTe-containing layer. Alternatively, the etched CdTe-containing layer may be dipped in a copper salt solution. In a third alternative, a copper/graphite paste may be screen printed onto the etched CdTe-containing layer. The disclosed etching composition helps to prevent this copper-containing dopant from migrating into the CdTe-containing layer and rendering the resulting solar cell less effective.

The back contact of the solar cell is then deposited onto the doped, etched CdTe-containing layer. Suitable back contacts include Mo, Cr, and ZnTe.

Applicants believe that the disclosed etching process provide improved stability of the solar cells and increased solar efficiency. The process may be done in one step or may be separated into two processes (etch followed by deposition of a complexing agent). The presence of the oxide-free Te-rich layer, combined with the copper complexing agent, keeps the copper at the back contact rather than allowing it to diffuse through the CdTe-containing layer to the CdS junction.

### EXAMPLES

The following examples illustrate experiments performed in conjunction with the disclosure herein. The ratio results provided were measured by glow discharge optical emission spectroscopy. The examples are not intended to be all inclusive and are not intended to limit the scope of disclosure described herein.

### Example 1

CdTe films were etched by the following etching composition:
25% w/w Acetic Acid
0.75% w/w Hydrogen Peroxide
1% w/w Polyethylene glycol surfactant
q.s. water

The initial Cd/Te ratio was 1:1. The CdTe ratio became 0.05-0.1:1 after approximately 10 seconds to approximately 20 seconds contact with the etching composition followed by a light rinse with deionized water. The final ratio depended upon etch time.

q.s.=quantum sufficit—as much as needed to make 100%

### Example 2

CdTe films were etched by the following etching composition:
20% w/w Citric Acid
0.75% w/w Hydrogen Peroxide
0.5% w/w Cysteine
q.s. water

The initial Cd/Te ratio was 1:1. The CdTe ratio became 0.05-0.2:1 after approximately 10 to approximately 20 seconds contact with the etching composition followed by a light rinse with deionized water. The final ratio depended upon etch time.

### Example 3

CdTe films were etched by the following etching composition:
25% w/w Gluconic Acid
0.75% w/w Hydrogen Peroxide
0.5% w/w Benzotriazole
q.s. water

The initial Cd/Te ratio was 1:1. The CdTe ratio became 0.1-0.3:1 after approximately 10 to approximately 20 seconds contact with the etching composition followed by a light rinse with deionized water. The final ratio depended upon etch time.

### Prophetic Example 4

Applicants believe that the disclosed etching compositions will provide improved efficiency results for the solar cells made by the disclosed process by modifying the Cd/Te ratio to Te rich (as demonstrated in Examples 1-3) and preventing the copper from diffusing into the CdTe-containing layer. The efficiency is a measure of the amount of light converted to electrical energy. Over extended periods of time, the solar cell's efficiency are known to decrease. Applicants believe that the disclosed etching compositions and methods will reduce the amount of this decrease by approximately 10% to approximately 50%, thereby maintaining the power output of the solar cell over a longer time period.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A method for etching the surface of a CdTe-containing layer, comprising:
a) providing a CdTe-containing layer; and
b) providing an etching composition to etch at least part of the layer, the etching composition comprising an acid, an oxidizer, and a complexing agent.

2. The method of claim 1, wherein providing the etching composition comprises spraying the etching composition on the CdTe-containing layer.

3. The method of claim 1, wherein providing the etching composition comprises moving the CdTe-containing layer through a tank containing the etching composition.

4. The method of claim 1, wherein the etching composition is provided for a time period ranging from approximately 1 second to approximately 60 seconds.

5. The method of claim 1, wherein the etching composition is not rinsed by deionized water from the CdTe-containing layer.

6. The method of claim 1, wherein the etching composition is provided at room temperature.

7. The method of claim 1, wherein the etching composition has a pH ranging from approximately 1 to approximately 5.

8. The method of claim 1, wherein the oxidizer is hydrogen peroxide.

9. The method of claim 8, wherein the acid is selected from the group consisting of gluconic acid, acetic acid, citric acid, and mixtures thereof.

10. The method of claim 8, wherein the complexing agent is selected from the group consisting of benzotriazole, cysteine, a glycolic acid ethoxylate lauryl ether surfactant, a polyethylene glycol surfactant, and mixtures thereof.

11. A method for etching the surface of a CdTe-containing layer, comprising:
a) providing a CdTe-containing layer; and
b) providing an etching composition to etch at least part of the layer, wherein the etching composition comprises a first mixture containing an acid and an oxidizer and a second mixture containing a complexing agent.

12. The method of claim 11, wherein providing the etching composition comprises spraying the first mixture on the CdTe-containing layer followed by spraying the second mixture on the CdTe-containing layer.

13. The method of claim 11, wherein providing the etching composition comprises moving the CdTe-containing layer through a first tank containing the first mixture and a second tank containing the second mixture.

14. The method of claim 13, further comprising rinsing the CdTe-containing layer after moving the CdTe-containing layer through the first tank containing the first mixture and prior to moving the CdTe-containing layer through the second tank containing the second mixture.

15. The method of claim 11, wherein the first mixture is provided for a time period ranging from approximately 1 second to approximately 60 seconds.

16. The method of claim 11, wherein the etching composition is provided at room temperature.

17. The method of claim 11, wherein the oxidizer is hydrogen peroxide.

18. The method of claim 17, wherein the acid is selected from the group consisting of gluconic acid, acetic acid, citric acid, and mixtures thereof.

19. The method of claim 17, wherein the complexing agent is selected from the group consisting of benzotriazole, cysteine, a glycolic acid ethoxylate lauryl ether surfactant, a polyethylene glycol surfactant, and mixtures thereof.

20. A composition for etching a CdTe-containing layer, comprising:
a) between approximately 5% w/w to approximately 50% w/w of an acid;
b) between approximately 0.5% w/w to approximately 5% w/w of an oxidizer; and
c) between approximately 0.01% w/w to approximately 3% w/w of a complexing agent.

21. The composition of claim 20, wherein the oxidizer is hydrogen peroxide.

22. The composition of claim 21, wherein the acid is selected from the group consisting of gluconic acid, acetic acid, citric acid, and mixtures thereof.

23. The composition of claim 21, wherein the complexing agent is selected from the group consisting of benzotriazole, cysteine, a glycolic acid ethoxylate lauryl ether surfactant, a polyethylene glycol surfactant, and mixtures thereof.
